(19) United States
(12) Patent Application Publication
(10) Pub. No.: US 2016/0377665 A1
(43) Pub. Date: Dec. 29, 2016

(54) WIRE HARNESS TESTING APPARATUS AND METHOD

(71) Applicant: John Caravella, East Hanover, NJ (US)

(72) Inventor: John Caravella, East Hanover, NJ (US)

(21) Appl. No.: 15/191,768

(22) Filed: Jun. 24, 2016

Related U.S. Application Data
(60) Provisional application No. 62/184,651, filed on Jun. 25, 2015.

(51) Int. Cl. G01R 31/02; G01R 31/00; G01R 1/04

(52) U.S. Cl. CPC G01R 31/021; G01R 1/0416; G01R 31/005

(57) ABSTRACT

The disclosed apparatus and method relates generally to the field of electrical testing and more particularly to an apparatus and method for the testing of wire harnesses, cable harnesses, wire assemblies and the like having a multiplicity of conductive wires for electrical defects including lack of continuity, opens, breaks and shorts without the need to remove a wire harness from its installed location.

This Application claims priority to Provisional U.S. Patent Application Ser. No. 62/184,651, filed on Jun. 25, 2015.

### FIELD OF THE INVENTION

The disclosed apparatus and method relates generally to the field of electrical testing and more particularly to an apparatus and method for the testing of wire harnesses, cable harnesses, wire assemblies and the like having a multiplicity of conductive wires (collectively “wire harness”) for electrical defects including lack of continuity, opens, breaks and shorts without the need to remove a wire harness from its installed location.

### BACKGROUND

Wire harnesses are commonly utilized in complex machinery, such as automobiles, aircraft, spacecraft and construction machinery, as well as electronics and telecommunications systems. It is common for wire harnesses to be comprised of a large number of separate conductive wires, sometimes in excess of 100.

Typically, a wire harness is comprised of numerous lengths of individual conductive wires with a multi-contact connector at one end and a multi-contact terminus at the other end, said multi-contact connectors and terminuses containing multiple individual electrical contacts. In most circumstances, each individual contact disposed in a multi-contact connector and/or terminus corresponds to an individual conductive wire contained in the wire harness. This allows a wire harness to be mated to multi-contact connections found in complex machinery and electronics. Depending on the type of wire harness, the harness may have only one multi-contact terminus (the multi-contact connector and multi-contact terminus are identical) or a plurality of disparate multi-contact connector terminuses (the multi-contact connector and multi-contact terminuses are not identical). The multi-contact connector and terminus of a specific wire harness are often unique to a specific type of machinery or electronics, resulting in a large number of different wire harness multi-contact connectors and terminuses.

Due to the complexity of a wire harness, defects are common. The type of defects that can exist in a wire harness include partial breaks in the conductive wires or connector contacts (“opens”), unwanted conduction pathways between two or more conductive wire or connector contacts (“shorts”), or complete breaks in the conductive wires or connector contacts (“breaks”) that lead to a lack of electrical continuity. These defects can be caused by manufacture error, damage, or normal wear and tear. Moreover, due to the fact that wire harnesses are often flexed or subject to movement during the normal operation of a piece of machinery or electronics, the aforementioned defects may only be present in certain positions or configurations, thus frustrating troubleshooting.

A defect in a wire harness often results in a partial or total loss of the functionality of machinery or electronics. In order to correct a wire harness defect, the defect in the harness must be isolated and located.

Multiple separate wire harnesses are often installed in a single piece of machinery or electronics, thus making access to a wire harness in its entirety extremely difficult or impossible. Likewise, especially regarding large complex machinery, removal of an installed wire harness is almost always infeasible. Notwithstanding these facts, current wire harness testing systems and methodology require both the multi-contact connector and all terminuses of a wire harness to be tested simultaneously to establish the presence of defect such as opens, shorts and/or breaks. Due to the fact that the multi-contact connector and all terminuses of a wire harness are often dispersed throughout a large piece of complex machinery, the testing of the multi-contact connector and all terminuses simultaneously is not feasible unless the entire wire harness is removed from the machine, something that is seldom feasible for complex machines. Thus, the wire harnesses of large complex machinery must be tested with the wire harness installed in the machinery, making it extremely difficult or impossible to test the multi-contact connector and all multi-contact terminuses simultaneously.

Due in part to this fact, heretofore, it has been a common practice to test an installed wire harnesses in a burdensome manual “conductive wire-by-conductive wire” fashion, whereby an electrical charge is manually supplied to each individual electrical contact in a multi-contact connector through the use of a singular probe or the like. Via this cumbersome method, an electrical charge is supplied to the individual conductive wire connected to the electrical contact, and the resultant voltage/current or other electrical measurement of the associated terminus electrical contact in a multi-contact terminus is measured. Often times, especially in the case of large complex machinery such as construction equipment, the multi-contact connector and associated terminuses are located a large distance apart, thus necessitating traveling to and from said connector and terminus time and time again during testing.

Thus, when a defect in a wire harnesses is suspected, the act of isolating said defect is highly burdensome, time consuming and expensive. This is especially true for large complex machinery and/or when a wire harness has a more than one multi-contact terminus.

Thus, the disclosed apparatus and method aims to provide for the simple, cost effective and efficient electrical testing of a wire harness, both installed and uninstalled, containing one or more multi-contact terminuses for electrical defects without the need to simultaneously test both a wire harness' multi-contact connector and all multi-contact terminuses.

Various wire harness testing apparatuses and methods in which both a wire harness' multi-contact connector and all terminuses must be tested simultaneously are known. Examples include U.S. Pat. No. 3,480,856; U.S. Pat. No. 2,814,774; U.S. Pat. No. 4,227,146; U.S. Pat. No. 5,231,357; and U.S. Pat. No. 5,514,966.

Thus, there remains an unmet need for an easy to use and cost effective wire harness testing apparatus and method capable of facilitating the testing of any wire harness, including but not limited to wire harnesses with more than one multi-contact terminus and/or wire harnesses installed in machinery for electrical defects, including lack of continuity, opens, breaks and shorts without the need to simultaneously test both a wire harness' multi-contact connector and all terminuses.

### SUMMARY OF THE INVENTION

The present invention provides for an apparatus and method to facilitate the testing of numerous unique and/or manufacture specific wire harnesses, including those with more than one multi-contact terminus and those installed in machinery, for electrical defects, including lack of continuity, opens, breaks and shorts.

### BRIEF DESCRIPTION OF THE DRAWINGS

FIG. 1 is a perspective view of a typical multi-terminus wire harness.

FIG. 2 is a perspective view of a multi-contact connector of a wire harness.

FIG. 3 is a top view of one embodiment of the disclosed apparatus.

FIG. 4 is a top view of another embodiment of the disclosed apparatus.

FIG. 5 is a perspective view of one embodiment of the universal multi-contact connector.

FIG. 6 is a perspective view of one embodiment of the universal multi-contact connector, the universal multi-contact connector adapter and a multi-contact connector of a wire harness.

### DETAILED DESCRIPTION

For clarity of disclosure, and not by way of limitation, the detailed description of the invention is divided into the following subsections that describe or illustrate certain features, embodiments, applications and examples of implementation of the invention.

### The Device of the Present Invention

One skilled in the relevant art will recognize that the techniques described herein can be practiced without one or more of the specific details, or with other methods, components, materials, etc., to obtain similar results and/or results in specific scenarios. In other instances, well-known structures, materials or operations are not shown or described in detail to avoid obscuring certain aspects.

Reference throughout this Application to “one embodiment” or “an embodiment” means that a particular feature, structure, or characteristic described in connection with the embodiment is included in at least one embodiment of the present invention. Thus, the appearances of the phrase “in one embodiment” or “in an embodiment” in various places throughout this Application are not necessarily all referring to the same embodiment. Furthermore, the particular features, structures, or characteristics may be combined in any suitable manner in one or more embodiments.

Each and every feature described herein, and each and every combination of two or more of such features, is included within the scope of the present invention provided that the features included in such a combination are not mutually exclusive.

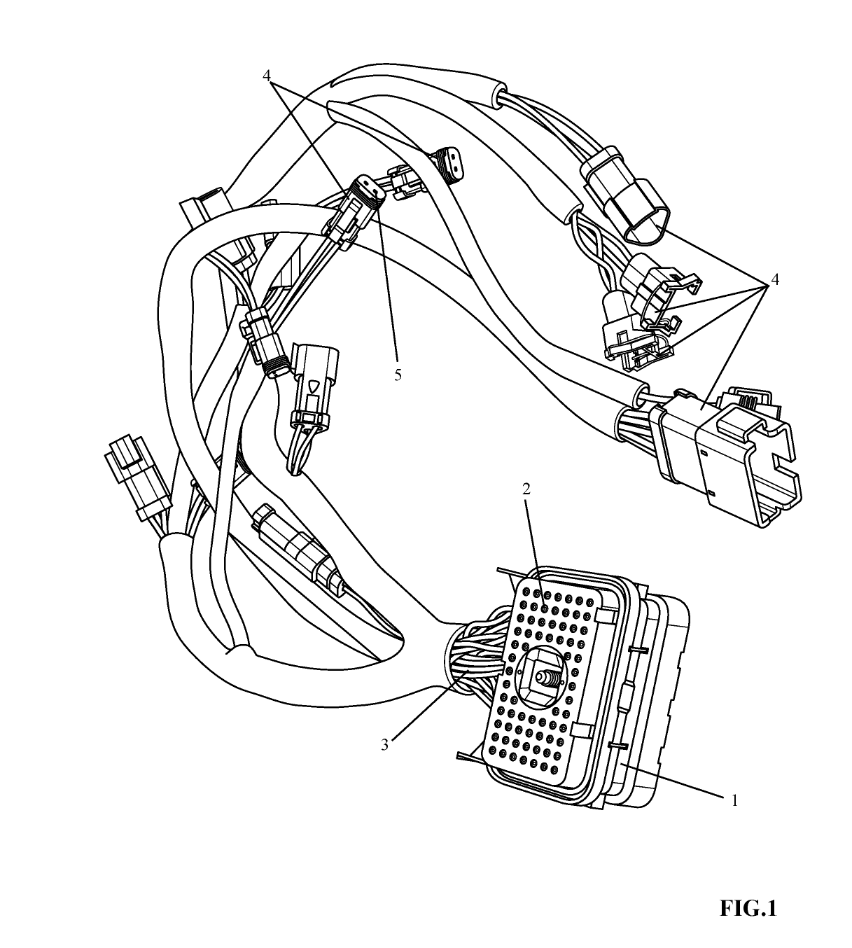

Turning now to the figures, FIG. 1 depicts the common layout of a multi-terminus wire harness, said harness comprised of a multi-contact connector (1) with multiple individual electrical contacts disposed therein (2), a plurality of conductive wires (3), each conductive wire connected to an individual electrical contact within the multi-contact connector (2), and multiple disparate multi-contact terminuses (4) with multiple individual electrical contacts disposed therein (5). In a typical arraignment, the multi-contact connector (1) is affixed to a control unit of a machine, while the disparate multi-contact terminuses (4) are dispersed throughout the machine and connected to numerous different features of said machine, such as actuators, lights, sensors, pumps, valves and the like. In the case of large construction equipment, a wire harness such as the one shown in FIG. 1 may contain over one hundred different conductive wires (3), have over ten different multi-contact terminuses (4), and may total over one hundred feet in length.

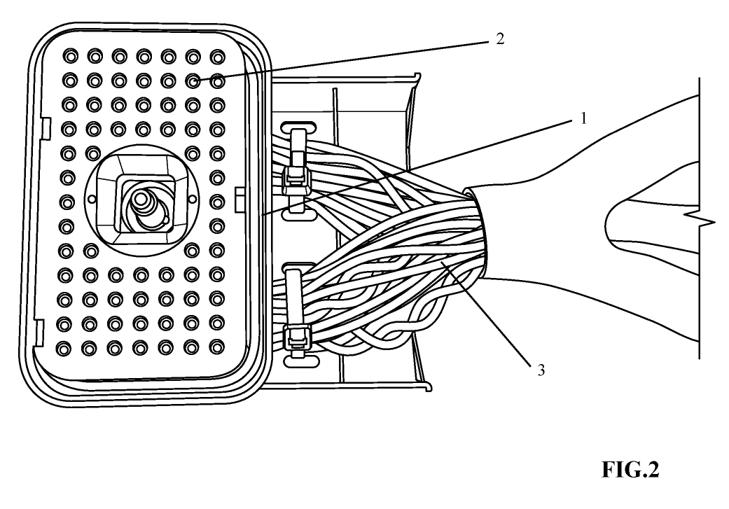

FIG. 2 depicts a common multi-contact connector (1) found on a wire harness comprising a plurality of individual electrical contacts (2), each contact connected to a separate individual conductive wire (3). In a properly functioning wire harness, an electrical charge applied to an individual electrical contact (2) of a multi-contact connector (1) will energize the connected conductive wire (3) and the associated electrical contact (5) disposed in a wire harness' multi-contact terminus (5).

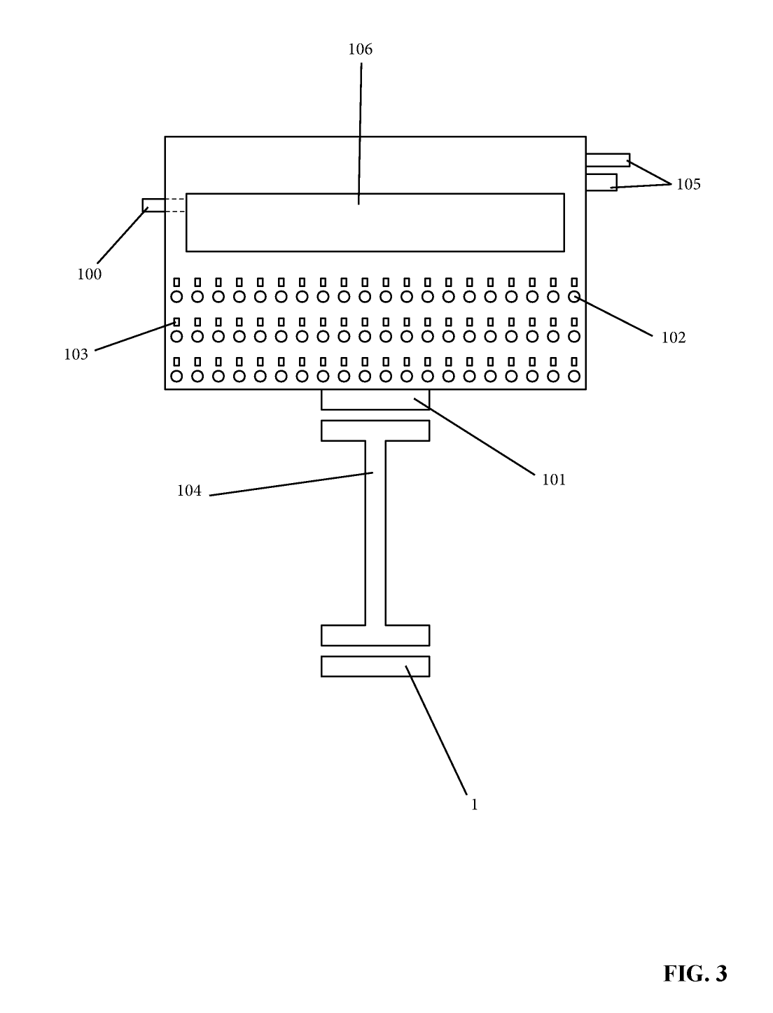

Turning now to FIG. 3, the apparatus in one embodiment is comprised of a power source (100), a universal multi-contact connector (101) containing a plurality of electrical contacts (108), a plurality of individual switches (102), each individual switch configured to regulate the flow of an electrical charge from the power source to a specific single electrical contact (108) contained in said universal multi-contact connector (101), a plurality of individual light sources (103), each individual light source connected to a single individual switch (102), wherein each individual light source is configured to indicate the flow of an electrical charge to a specific individual electrical contact (108) contained in said universal multi-contact connector (101), and a universal multi-contact connector adapter (104) configured to removably affix to a wide variety of multi-contact connectors (1) found on various wire harnesses. The apparatus may have an alternative power source (105) and/or an internal rechargeable battery (106).

The power source may be any constant power supply. The power source may be a rechargeable battery (106) disposed within the body of the apparatus and/or any 12 volt power supply. The apparatus may also have an alternative power supply (105) which may comprise conductive wires and alligator clips configured to attach to the terminals of any external battery, such as a car battery or the like. The individual light sources (103) may be comprised of LEDs or any other low voltage light source.

Each individual switch (102) may be numbered, said number corresponding to an identical number assigned to the specific individual electrical contact (108) disposed in said universal multi-contact connector (101) controlled by said switch (102).

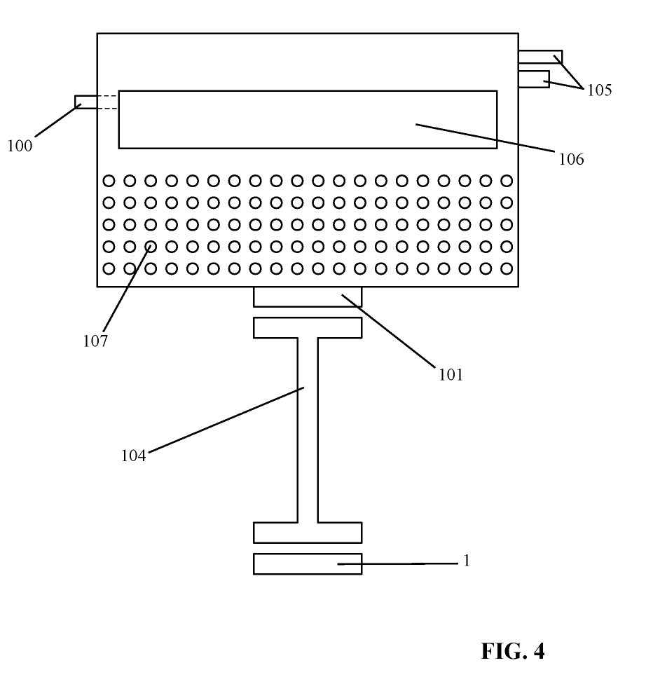

FIG. 4 shows an alternative embodiment of the disclosed apparatus showing a power source (100), a universal multi-contact connector (101) containing a plurality of electrical contacts (108), a plurality of individual switches with an integrated light source (107), a universal multi-contact connector adapter (104) adapted to removably affix to various multi-contact connectors (1) found on various wire harnesses, an alternative power source (105) and internal rechargeable battery (106). In this embodiment, the closure of any of the individual switches (107) also illuminates an integrated light source disposed within or under said switch to indicate that an electrical charge is flowing from the power source to the specific individual electric contact (108) within the universal multi-contact connector (101) associated with the closed switch.

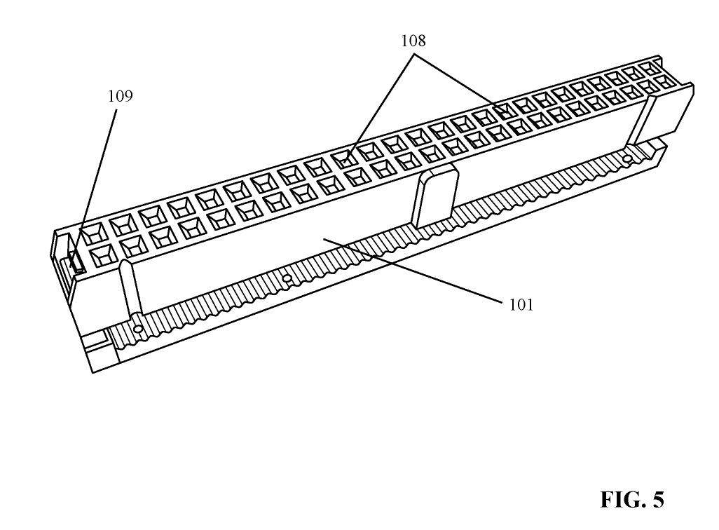

One embodiment of the universal multi-contact connector (101) is shown by FIG. 5. The universal multi-contact connector (101) is comprised of a plurality of separate individual electrical contacts (108). Each individual electrical contact is fully isolated such that the application or removal of an electrical charge to any other electrical contact disposed within the universal multi-contact connector does not affect any other electrical contact. The plurality of separate individual electrical contacts (108) may be comprised of female contacts, as shown in FIG. 5, or male contacts. The plurality of separate individual electrical contacts (108) may also be comprised of a combination of male and female contacts. Each individual electrical contact (108) is electrically connected to a single individual switch (102/107) disposed within the apparatus such that when the switch associated with the individual contact is pushed (closed), an electrical charge flows from the power source (100, 105, 106) to the electrical contact (108) associated with the individual switch. Any combination of switches (102/107) may be closed simultaneously, thus providing an electrical charge to any combination of individual electrical contacts (108) disposed within the universal multi-contact connector (101). The universal multi-contact connector may also contain removable fixation means (109) for the attachment of the universal multi-contact connector adapter (104).

The universal multi-contact connector (101) may be comprised of any number of separate individual contacts (108). In one embodiment, there are one hundred separate individual electrical contacts. In another embodiment, there are fifty separate individual electrical contacts. In all instances, the number of individual switches (102/107) and light sources (103) would be equal to the number of separate individual contacts (108) contained in the universal multi-contact connector (101).

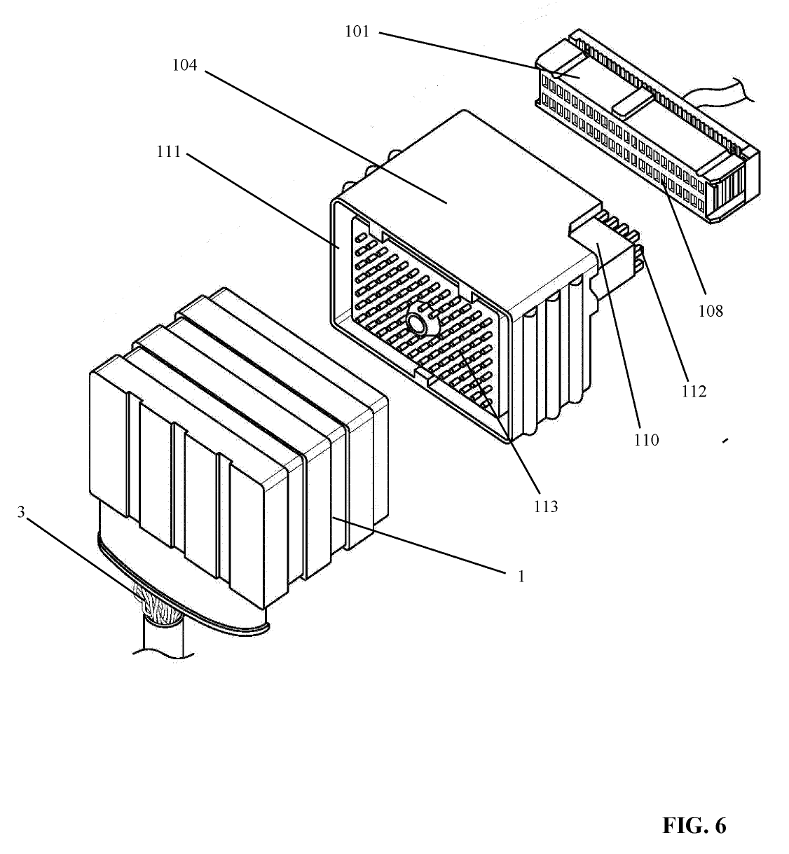

FIG. 6 shows one embodiment of the universal multi-contact connector adapter (104) as well as the universal multi-contact connector (101) and a multi-contact connector of a wire harness (1). The universal multi-contact connector (101) is electrically connected to the power source (100, 105, 106) of the apparatus with the electrical charge from said power source controlled by the plurality of switches (102/107). The universal multi-contact connector adapter (104) is comprised of a universal multi-contact connection side (110) and a multi-contact connector side (111). The universal multi-contact connection side of the adapter (110) is comprised of a plurality of electrical contacts (112) that correspond to the electrical contacts (108) of the universal multi-contact connector (101). The adapter, via the universal multi-contact connector side (110) removably attaches to the universal multi-contact connector (101). Once attached, an electrical charge can flow from the universal multi-contact connector (101) into the universal multi-contact connector adapter (104). The multi-contact connection side of the adapter (111) is comprised of plurality individual electrical contacts (113) that correspond to the electrical contacts of the appropriate multi-contact connector of the wire harness being tested (1). The multi-contact connector side of the universal multi-contact connector adapter (111) is further adapted to removably affix to the multi-contact connector of the wire harness being tested (1). Each individual electrical contact contained in the multi-contact connection side of the adapter (113) is electrically connected to a corresponding individual specific electrical contact on the universal multi-contact connector side of the adapter (112). Once the adapter (104) is affixed to both the universal multi-contact connector (101) and the subject wire harness' multi-contact connector (1), if an electrical charge is supplied to a specific electrical contact (108) of the universal multi-contact connector (101) via the closure of the associated switch (102/107) located on the body of the apparatus, said charge will flow from the power source through the electrical contact (108) of the universal multi-contact connector (101) through the multi-contact connector adapter (104) and into an individual electrical contact (2) of the attached wire harness' multi-contact connector (1) thereby providing an electrical charge to the individual conductive wire (3) connected to individual contact of the harness' multi-contact connector (2). The electrical contact (5) disposed within corresponding multi-contact terminus (4) connected to the subject conductive wire would also be provided with an electrical charge/energized. In this manner, the apparatus and method disclosed herein can selectively energize any conductive wire and/or associated electrical contact disposed within the appropriate multi-contact terminus, or any combination of the same contained in an attached wire harness, thus allowing for the testing of the wire harness for electrical defects.

The electrical contacts (113) disposed within multi-contact connector side of the universal multi-contact connector adapter (104) may be numbered such that said number corresponds to the individual switch (102/107) number that controls the flow of the electrical charge to said electrical contact (113).

The universal multi-contact connector (101) may also be removably attachable to a configurable multi-contact connector adapter. The configurable multi-contact connector adapter is configured to supply an electrical charge to specific individual electrical contacts (2) of any multi-contact connector (1). The configurable multi-contact connector adapter may be comprised of a universal multi-contact connection side (110) identical to FIG. 6, but with a multi-contact connector side (111) comprised of a plurality of conductive wires, each said wire terminating in a male and/or female electrical connection. Each individual conductive wire is electrically connected to a single electrical contact found on the universal multi-contact connection side (112) of the configurable multi-contact connector adapter. Thus, any number of the adapter's conductive wires can be removably attached to specific electrical contacts (2) of a wire harness' multi-contact connector, thereby enabling a user to selectively energize any conductive wire and associated electrical contact disposed in the appropriate multi-contact terminus, or any combination of the same contained in an attached wire harness.

### Examples

For clarity of disclosure, the following example is based on one specific use of the disclosed apparatus and method in connection with a complex piece of construction machinery. One of ordinary skill in the art will appreciate the many applications and embodiments of the device of the present invention.

The owner of a piece of large complex construction machinery, such as a backhoe as manufactured by CATERPILLAR® or JOHN DEERE® experiences a loss of functionality of one or more features of the backhoe. After a thorough examination of the backhoe, all mechanical systems appear to be in order, and thus, damage to the wire harness of the backhoe is suspected. The subject wire harness has a single multi-contact connector affixed to the central control unit of the backhoe and several disparate multi-contact terminuses disposed throughout the backhoe. In this instance, the disclosed apparatus and method can be utilized to quickly and efficiently check the wire harness for damage and/or defects.

First, based upon the backhoe's manufacture and model, the user would obtain the universal multi-contact connector adapter (104) that is known to fit the wire harness' multi-contact connector (1). The user would plug the universal multi-contact connector adapter (104) into the universal multi-contact connector (101) of the apparatus. The user would then consult the manufacture's wiring diagram for the subject backhoe, which maps the subject wire harness and its multiple terminus locations, and also provides the identity of each conductive wire (3) within the wire harness and the electrical contact location (2) for each wire within the wire harness' multi-contact connector (1). In this manner, the user can identify the specific electrical contacts (2) of the multi-contact connector (1) he or she may need to supply with an electrical charge in order to test various aspects of the wire harness. For example, if the digger attachment of the subject backhoe is not functioning, only the conductive wires of the wire harness relating to the digger attachment need to be tested. Through the use of the manufacture's wiring diagram, the user can identify the specific conductive wires which control the digger attachment, and thus, identify the specific electrical contacts (2) within the multi-contact connector (1) that need to be provided with an electrical charge to test the wire harness in relation to only the digger attachment.

With the specific electrical contacts (2) disposed within the multi-contact connector (1) identified, the user can then selectively energize the identified contacts by attaching the multi-contact connector to the universal multi-contact connector adapter (104) and selectively closing the individual switches (102/107) associated with the specific identified electrical contacts, thus selectively energizing the conductive wires connected to the contacts. Once the desired conductive wire(s) is energized, a user can check for electrical defects, such as lack of continuity, opens, breaks and shorts by assessing the electrical properties/readings at the multi-contact terminus contact (5) associated with the energized conductive wire.

A user can assess the electrical properties/readings at the subject multi-contact terminus contact (5) through the use of a voltmeter, a substantial equivalent, or other device capable of determining and measuring electrical properties, thus ascertaining if power is reaching the terminus contact by comparing the expected voltage, electric flow or other electrical property against the actual reading recorded at the multi-connector terminus contact by the user. If the proper power (or voltage/electric flow) is registered at subject the multi-contact terminus contact, no break exists in the conductive wire associated with the subject multi-contact terminus contact. If no power, or low power (or voltage) is registered at subject the multi-contact terminus contact, a break or open is present in the conductive wire associated with the multi-contact terminus contact. In a similar manner, testing for shorts can be conducted by testing multi-contact terminus contacts (5) associated with non-energized conductive wires for power. If power is registered at a multi-contact terminus contact not connected to an intentionally energized conductive wire, a short is present between the intentionally energized conductive wire and the conductive wire connected to the improperly energized multi-contact terminuses contact.

In a similar manner, a user can also quickly check if all a multi-contact terminus contacts (5) within a designated individual multi-contact terminus (4) are receiving electrical power by selectively applying an electrical charge to all contacts (2) in the multi-contact connector (1) connected via conductive wire to the designated multi-contact terminus contacts (5) and checking for power at all multi-contact terminus contacts.

Publications cited throughout this document are hereby incorporated by reference in their entirety. Although the various aspects of the invention have been illustrated above by reference to examples and preferred embodiments, it will be appreciated that the scope of the invention is defined not by the foregoing description but by the following claims properly construed under principles of patent law.

What is claimed is:

1. An wire harness testing apparatus comprising:
A power source;
A universal multi-contact connector containing a plurality of electrical contacts;
A plurality of individual switches, each individual switch configured to regulate the flow of an electrical charge from the power source to a specific single electrical contact disposed within said universal multi-contact connector; and
A universal multi-contact connector adapter configured to physically and electrically connect to both the universal multi-contact connector and the multi-contact connector of a specific wire harness.

2. The apparatus of claim 1 further comprising a plurality of individual light sources, each individual light source connected to an individual switch, wherein each individual light source is configured to illuminate upon the presence of a flow of an electrical charge to the specific individual electrical contact disposed within said universal multi-contact connector connected to said switch; and

3. The apparatus of claim 1 wherein the power source is any constant power supply.

4. The apparatus of claim 1 wherein the power source is a battery disposed within the apparatus.

5. The apparatus of claim 1 wherein the power souse is any 12 volt power supply.

6. The apparatus of claim 1 further comprising an auxiliary power source consisting of a pair of conductive wires and alligator clips.

7. The apparatus of claim 1 wherein the universal multi-contact adapter is a configurable universal multi-contact adapter comprising a plurality of conductive wires, each said wire terminating in a male and/or female electrical connection.

8. A method of testing a wire harness for electrical defects comprising the steps of:
Ascertaining the location of the specific electrical contacts disposed within a multi-contact connector of a wire harness connected to the conductive wire to be tested;
Selectively applying an electric charge to one or more of the conductive wires, through the multi-contact connectors, via the use of a single apparatus;
Recording the electrical properties at the electrical contact disposed within a multi-contact terminus connected to the conductive wire being tested; and
Comparing the recorded electrical properties to the expected electrical properties that would be present at said electrical contact if the conductive wire were functioning properly.
